(19) United States
(12) Patent Application Publication
(10) Pub. No.: US 2016/0218190 A1
(43) Pub. Date: Jul. 28, 2016

(54) SEMICONDUCTOR DEVICE AND METHOD FOR MANUFACTURING SEMICONDUCTOR DEVICE

(71) Applicant: Toyota Jidosha Kabushiki Kaisha, Toyota-shi Aichi-ken (JP)

(72) Inventors: Yuji Fukuoka, Toyota-shi Aichi-ken (JP); Yukihiko Watanabe, Nagakute-shi Aichi-ken (JP); Shinichiro Miyahara, Kariya-shi Aichi-ken (JP)

(21) Appl. No.: 15/005,310

(22) Filed: Jan. 25, 2016

(30) Foreign Application Priority Data
Jan. 27, 2015 (JP) 2015-012942

(51) Int. Cl. H01L 29/423; H01L 21/324; H01L 21/283

(52) U.S. Cl. CPC H01L 29/4236; H01L 21/283; H01L 21/324

(57) ABSTRACT

A semiconductor device includes: a semiconductor substrate; and a first trench and a second trench that extend from a front surface of the semiconductor substrate toward a rear surface side of the semiconductor substrate. A gate electrode is accommodated in the first trench. An insulator is accommodated in the second trench. An angle between a bottom surface and a side surface of the first trench is larger than an angle between a bottom surface and a side surface of the second trench. A void is provided in the insulator in the second trench.

### CROSS-REFERENCE TO RELATED APPLICATION

This application claims priority to Japanese Patent Application No. 2015-012942 filed on Jan. 27, 2015, the contents of which are hereby incorporated by reference into the present application.

### TECHNICAL FIELD

The present application relates to a semiconductor device and a method for manufacturing a semiconductor device.

### DESCRIPTION OF RELATED ART

A semiconductor device disclosed in Japanese Patent Application Publication No. 2006-128507 includes a semiconductor substrate, and first and second trenches extending from a front surface of the semiconductor substrate toward a rear surface side thereof. A gate electrode is accommodated in the first trench, and an insulator is accommodated in the second trench.

### SUMMARY

In a semiconductor device of Japanese Patent Application Publication No. 2006-128507, an insulator filled in a second trench expands and contracts relative to a semiconductor substrate by a temperature change during operation. Further, heating process performed upon manufacturing the semiconductor device causes the insulator accommodated in the second trench to expand and contract relative to the semiconductor substrate. When the insulator accommodated in the second trench expands or contracts relative to the semiconductor substrate, thermal stress acts on the insulator and the semiconductor substrate, and a crack may be generated in the insulator and/or the semiconductor substrate. The present specification provides a technique that suppresses a generation of a crack in an insulator and/or a semiconductor substrate.

In one aspect of the present teachings, a semiconductor device comprises: a semiconductor substrate; and a first trench and a second trench that extend from a front surface of the semiconductor substrate toward a rear surface side of the semiconductor substrate. A gate electrode is accommodated in the first trench. An insulator is accommodated in the second trench. An angle between a bottom surface and a side surface of the first trench is larger than an angle between a bottom surface and a side surface of the second trench. A void is provided in the insulator in the second trench.

According to the semiconductor device comprising the above configuration, the void provided within the insulator can relax the thermal stress generated due to the relative expansion or contraction of the insulator, even if the insulator accommodated in the second trench expands or contracts relative to the semiconductor substrate by a temperature change during an operation of the semiconductor device. Due to this, the thermal stress acting on the insulator and the semiconductor substrate can be relaxed, and the generation of a crack in the insulator and/or the semiconductor substrate can be prevented.

In another aspect of the present teachings, a novel manufacturing method is disclosed. A method of manufacturing a semiconductor device disclosed herein comprises: forming a first trench and a second trench that extend from a front surface of a semiconductor substrate toward a rear surface side of the semiconductor substrate; depositing an insulator into the first trench and the second trench; and heating the semiconductor substrate after the depositing. In the forming of the first and second trenches, the first and second trenches are formed so that an angle between a bottom surface and a side surface of the first trench is larger than an angle between a bottom surface and a side surface of the second trench.

According to the above method of manufacture, a void can be formed in an insulator deposited in the second trench by using the difference in the angle between a bottom surface and a side surface of the first trench and the angle between a bottom surface and a side surface of the second trench upon the depositing. This will be described below.

In the above method of manufacture, in the forming of the first and second trenches, the first and second trenches are formed so that an angle between a bottom surface and a side surface of the first trench is larger than an angle between a bottom surface and a side surface of the second trench. As a result, a difference in trench widths at a bottom and an opening of the first trench becomes large, as compared to a smaller difference in trench widths at a bottom and an opening of the second trench. Further, in the depositing of the insulator in the first trench and the second trench, the insulator is deposited at a faster rate in a vicinity of the opening rather than in a vicinity of the bottom in both of the first and second trenches, due to a difference in deposition speed of the insulator. At this occasion, since the difference in the trench width is large between the bottom and the opening of the first trench, the insulator is deposited orderly from the bottom toward the opening before the vicinity of the opening is filled by the insulator, despite the difference in the deposition speed of the insulator. Thus, the vicinity of the opening is filled by the insulator at last. That is, the vicinity of the opening is not filled by the insulator before a portion deeper than the opening is filled by the insulator. As compared to this, due to the smaller difference in trench widths at the bottom and the opening of the second trench, a vicinity of the opening is filled by the insulator before the second trench is filled orderly from the bottom toward the opening due to the difference in the deposition speed of the insulator. As a result, the vicinity of the opening is filled by the insulator before a portion deeper than the opening is filled by the insulator, and the void is formed in the insulator deposited in the second trench.

Due to such a formation of the void in the insulator in the second trench, even if the insulator accommodated in the second trench expands or contracts relative to the semiconductor substrate by the temperature change during the operation of the semiconductor device, the void provided within the insulator can relax the thermal stress generated due to the relative expansion or contraction of the insulator.

### BRIEF DESCRIPTION OF DRAWINGS

FIG. 1 is an upper surface view of a semiconductor device of an embodiment;

FIG. 2 is a cross sectional view along II-II in FIG. 1;

FIG. 3 is a cross sectional view of a primary part of a semiconductor substrate;

FIG. 4 is a diagram (1) explaining a method of manufacturing the semiconductor device;

FIG. 5 is a diagram (2) explaining the method of manufacturing the semiconductor device;

FIG. 6 is a diagram (3) explaining the method of manufacturing the semiconductor device;

FIG. 7 is a cross sectional view of a primary part of the semiconductor substrate;

FIG. 8 is a diagram (4) explaining the method of manufacturing the semiconductor device;

FIG. 9 is a diagram (5) explaining the method of manufacturing the semiconductor device;

FIG. 10 is a cross sectional view of a primary part of the semiconductor substrate;

FIG. 11 is a cross sectional view of a primary part of the semiconductor substrate;

FIG. 12 is a diagram (6) explaining the method of manufacturing the semiconductor device;

FIG. 13 is a diagram (7) explaining the method of manufacturing the semiconductor device;

FIG. 14 is a diagram (8) explaining the method of manufacturing the semiconductor device; and

FIG. 15 is a cross sectional view of a primary part of the semiconductor substrate.

### DETAILED DESCRIPTION OF THE EMBODIMENTS

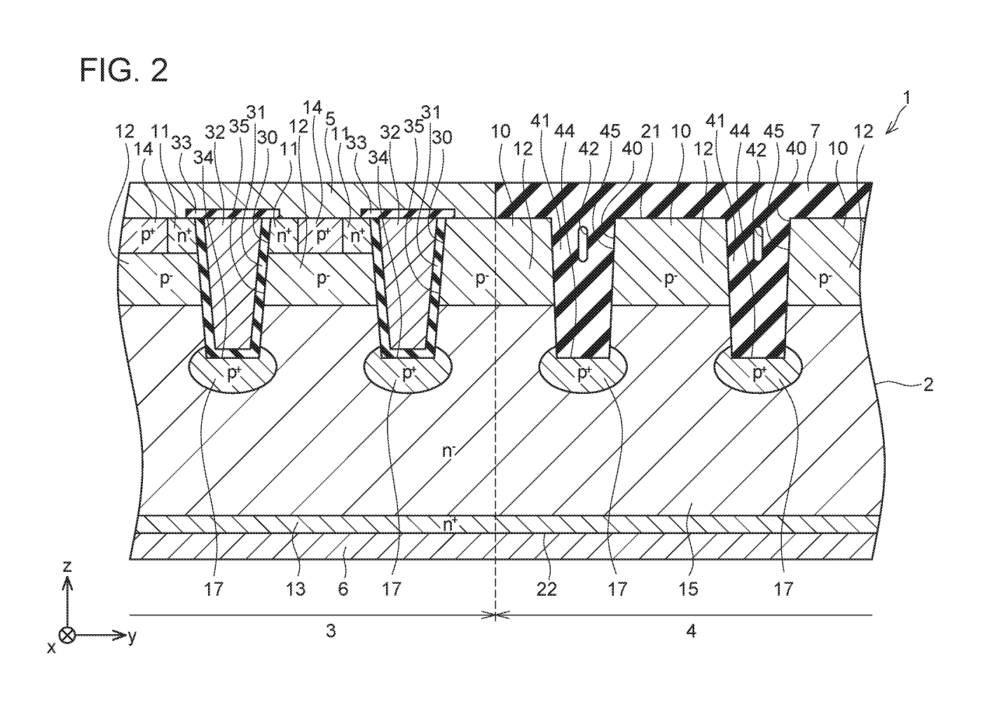

As shown in FIG. 2, a semiconductor device 1 of the present embodiment comprises a semiconductor substrate 2, front surface electrodes 5 provided in parts of a front surface 21 of the semiconductor substrate 2, a front surface insulation film 7 provided on another part of the front surface 21, and a rear surface electrode 6 provided on a rear surface 22.

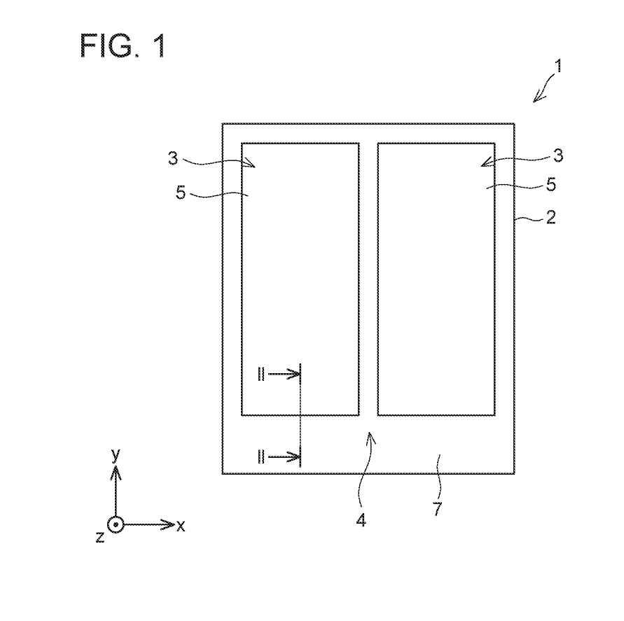

As shown in FIG. 1, the semiconductor substrate 2 has a rectangular shape as seen from its top view. The semiconductor substrate 2 is made of silicon carbide (SiC). The semiconductor substrate 2 comprises element regions 3 and a peripheral region 4. The element regions 3 are positioned on an inner side than the peripheral region 4. The element regions 3 comprise semiconductor elements. In the present embodiment, vertical MOSFETs (Metal Oxide Semiconductor Field Effect Transistors) are provided in the element regions 3. The peripheral region 4 is positioned on an outer side than the element regions 3. A breakdown voltage resisting structure is provided in the peripheral region 4.

As shown in FIG. 2, the front surface electrode 5 is provided on the front surface 21 in each element region 3 of the semiconductor substrate 2. The rear surface electrode 6 is provided on the rear surface 22 over the element regions 3 and the peripheral region 4 of the semiconductor substrate 2. The front surface electrodes 5 and the rear surface electrode 6 are made for example of metal such as aluminum (Al) or copper (Cu).

The front surface insulation film 7 is provided on the front surface 21 of the semiconductor substrate 2 in the peripheral region 4. The front surface insulation film 7 covers the front surface 21 in the peripheral region 4. The front surface insulation film 7 is made for example of silicon oxide (SiO2). The silicon oxide is deposited on the front surface 21 of the peripheral region 4 of the semiconductor substrate 2.

The semiconductor substrate 2 comprises a plurality of gate trenches 30 (an example of a first trench) and a plurality of terminal trenches 40 (an example of a second trench). The gate trenches 30 are provided in the element regions 3. The terminal trenches 40 are provided in the peripheral region 4. Further, the semiconductor substrate 2 comprises, in this order from a rear surface 22 side toward the front surface 21, a drain region 13, a drift region 15, and a base region 12. The drain region 13, the drift region 15, and the base region 12 are provided in common for all of the element regions 3 and the peripheral region 4. The semiconductor substrate 2 further comprises source regions 11, contact regions 14, and floating regions 17. The source regions 11 and the contact regions 14 are provided in the element regions 3. The floating regions 17 are provided respectively in all of the element regions 3 and the peripheral region 4.

Each of the gate trenches 30 extends from the front surface 21 toward a rear surface 22 side of the semiconductor substrate 2 (z direction). The gate trenches 30 extend from the front surface 21 of the semiconductor substrate 2 by penetrating the source regions 11 and the base region 12 to positions reaching the drift region 15. A gate electrode 32 and a gate insulator 31 are formed in each of the gate trenches 30.

The gate electrodes 32 are made for example of aluminum or polysilicon. The gate electrodes 32 are accommodated inside the respective gate trenches 30. Each of the gate electrodes 32 is accommodated on an inner side than the corresponding gate insulator 31. An interlayer insulation film 33 is disposed on each gate electrode 32. The interlayer insulation films 33 insulate the gate electrodes 32 from the front surface electrode 5.

The gate insulators 31 are made for example of silicon oxide (SiO₂). Each gate insulator 31 is provided on an inner surface of the corresponding gate trench 30. Each gate insulator 31 is disposed between the corresponding gate electrode 32 and the semiconductor substrate 2. The gate insulators 31 insulate the gate electrodes 32 from the semiconductor substrate 2.

Each of the terminal trenches 40 extends from the front surface 21 toward the rear surface 22 side of the semiconductor substrate 2 (z direction). The terminal trenches 40 extend from the front surface 21 of the semiconductor substrate 2 by penetrating the base region 12 to positions reaching the drift region 15. The terminal trenches 40 are provided at positions separated away from the gate trenches 30.

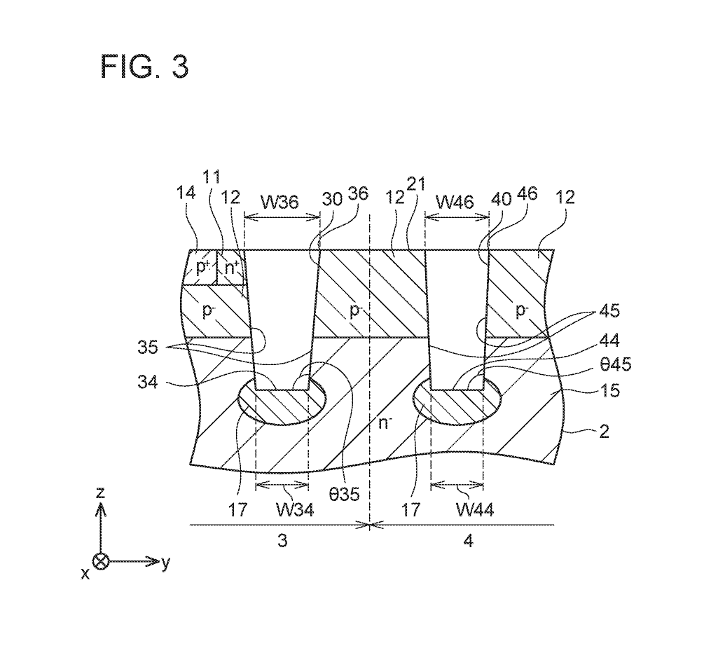

As shown in FIG. 3, an angle θ35 between a bottom surface 34 and a side surface 35 of each gate trench 30 is larger than an angle θ45 between a bottom surface 44 and a side surface 45 of each terminal trench 40. An inclination of the side surface 35 relative to the bottom surface 34 of each gate trench 30 is smaller than an inclination of the side surface 45 relative to the bottom surface 44 of each terminal trench 40. The inclination of the side surface 35 relative to the bottom surface 34 of each gate trench 30 is constant from the bottom surface 34 to an opening 36 of each gate trench 30. Further, the inclination of the side surface 45 relative to the bottom surface 44 of each terminal trench 40 is constant from the bottom surface 44 to an opening 46 of each terminal trench 40.

A width w46 of each opening 46 in a short direction (y direction) of the terminal trenches 40 is smaller than a width w36 of each opening 36 in a short direction (y direction) of the gate trenches 30. A width w44 of the bottom surface 44 in the short direction (y direction) of the terminal trenches 40 is same as a width w34 of each bottom surface 34 in the short direction (y direction) of the gate trenches 30.

As shown in FIG. 2, an insulator 41 is accommodated in the terminal trenches 40. Only the insulator 41 is accommodated in the terminal trenches 40, and no gate electrode is accommodated therein. Silicon oxide (SiO₂) may be used for the insulator 41. The insulator 41 is made of a same material as the front surface insulation film 7 and the gate insulators 31. The insulator 41 is integrated with the front surface insulation film 7. The insulator 41 makes tight contact with the side surfaces 45 and the bottom surfaces 44 of the terminal trenches 40. The insulator 41 is filled from the bottom surface 44 to the opening 46 of each terminal trench 40.

Voids 42 are provided in the insulator 41. Each void 42 is positioned between portions of the base region 12 that are exposed at both side surfaces 45 of a corresponding terminal trench 40 when seen along a vertical cross section of the substrate 2. The voids 42 are provided at positions in a vicinity of the front surface 21 of the semiconductor substrate 2. Each void 42 is provided at a center portion of the corresponding terminal trench 40 along the short direction (y direction) of the terminal trenches 40. A width of each void 42 in the short direction (y direction) of the terminal trenches 40 is smaller than a width of the void 42 in a depth direction (z direction) of the terminal trenches 40. Each void 42 extends continuously in a depthwise direction of a sheet surface of FIG. 2 (x direction). When the angle θ35 between the bottom surface 34 and the side surface 35 of each gate trench 30 is larger than the angle θ45 between the bottom surface 44 and the side surface 45 of each terminal trench 40, the voids 42 are generated upon filling the insulator 41 in the terminal trenches 40.

The drain region 13 is an n-type region. The drain region 13 has a high impurity concentration. The drain region 13 is provided on a rear surface side of the drift region 15. The drain region 13 is provided in an area exposed on the rear surface 22 of the semiconductor substrate 2. The drain region 13 makes ohmic contact with the rear surface electrode 6.

The drift region 15 is an n-type region. The drift region 15 has an impurity concentration that is lower than that of the drain region 13. The drift region 15 is provided on a front surface side of the drain region 13. The drift region 15 is provided between the base region 12 and the drain region 13.

The base region 12 is a p-type region. The base region 12 has a low impurity concentration. The base region 12 is provided in an area on a front surface side of the drift region 15 and making contact with the gate insulators 31. When a positive voltage is applied to the gate electrodes 32, the base region 12 inverts to an n-type at positions facing the gate electrodes 32 via the gate insulators 31.

The source regions 11 are n-type regions. The source regions 11 have a high impurity concentration. The source regions 11 are provided in areas on a front surface side of the base region 12 and making contact with the gate insulators 31. The source regions 11 are provided in island shapes in an area exposed on the front surface 21 of the semiconductor substrate 2. The source regions 11 make ohmic contact with the front surface electrode 5.

The contact regions 14 are p-type regions. The contact regions 14 have an impurity concentration higher than that of the base region 12. The contact regions 14 are provided in areas on the front surface side of the base region 12 and between adjacent source regions 11. The contact regions 14 are provided next to the source regions 11. The contact regions 14 are provided in island shapes in an area exposed on the front surface 21 of the semiconductor substrate 2. The contact regions 14 make ohmic contact with the front surface electrode 5.

The floating regions 17 are p-type regions. The floating regions 17 have a high impurity concentration. The floating regions 17 are provided around bottoms of the gate trenches 30 and around bottoms of the terminal trenches 40. The floating regions 17 are surrounded by the drift region 15. The floating regions 17 are separated from the base region 12 by the drift region 15. The plurality of floating regions 17 is separated from each other by the drift region 15. Potentials of the floating regions 17 are in a floating state.

In using the semiconductor device 1 having the above configuration, a voltage with which the rear surface electrode 6 is to become positive is applied between the front surface electrode 5 and the rear surface electrode 6. Further, an on-potential (potential that is equal to or more than a potential required for channel formation) is applied to the gate electrodes 32. When the on-potential is applied to the gate electrodes 32, channels are generated in the base region 12 in areas making contact with the gate insulators 31. Due to this, each MOSFET turns on. In so doing, electrons flow to the rear surface electrode 6 from the front surface electrode 5 via the source regions 11, the channels formed in the base region 12, the drift region 15, and the drain region 13. According to this, current flows from the rear surface electrode 6 to the front surface electrode 5.

As is apparent from the above description, in the aforementioned semiconductor device, the angle θ35 between the bottom surface 34 and the side surface 35 of each gate trench 30 is larger than the angle θ45 between the bottom surface 44 and the side surface 45 of each terminal trench 40, and the voids 42 are formed in the insulator 41 in the terminal trenches 40. Due to this, even if the insulator 41 accommodated in the terminal trenches 40 expand or contract relative to the semiconductor substrate 2 by the temperature change during the operation of the semiconductor device 1, the voids 42 formed in the insulator 41 can relax the thermal stress generated by the relative expansion or contraction of the insulator 41. Due to this, the stress acting on the insulator 41 and/or the semiconductor substrate 2 can be mitigated, and the generation of a crack in the insulator 41 and/or the semiconductor substrate 2 can be prevented.

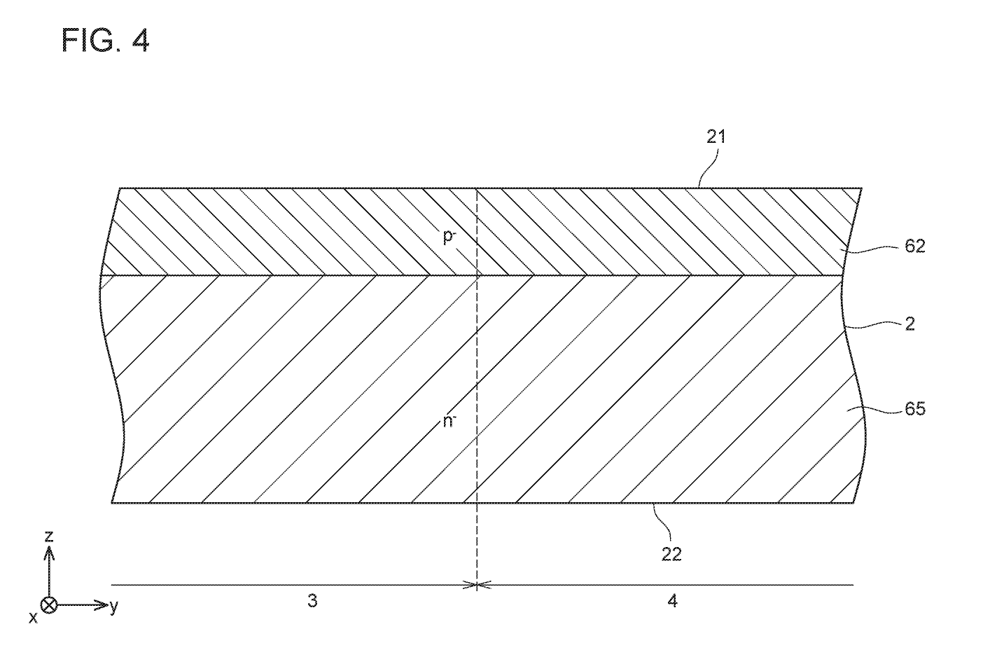

Next, a method of manufacturing a semiconductor device will be described. In manufacturing the aforementioned semiconductor device 1, firstly, as shown in FIG. 4, a p-type semiconductor layer 62 is grown epitaxially on an n-type SiC substrate 65. Due to this, the semiconductor substrate 2 comprising the n-type SiC substrate 65 and the p-type semiconductor layer 62 is formed. The SiC substrate 65 being a lower layer becomes the n-type drift region 15, and the semiconductor layer 62 being an upper layer becomes the p-type base region 12. The base region 12 is formed on the front surface side of the drift region 15.

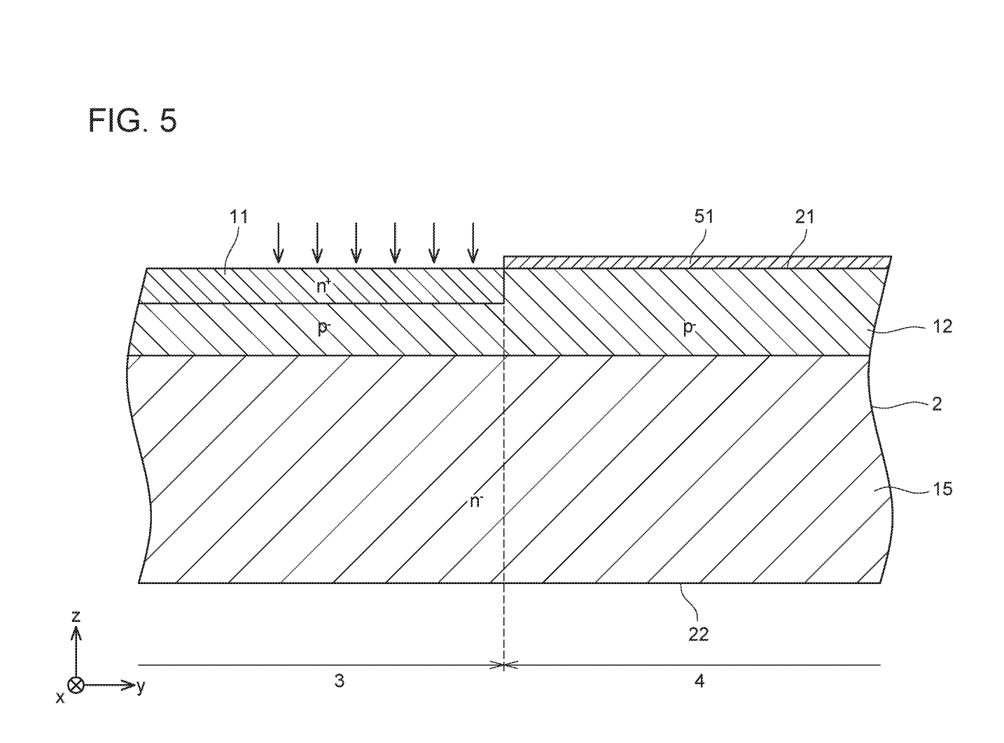

Next, as shown in FIG. 5, a mask 51 is formed on the front surface 21 of the semiconductor substrate 2 for the peripheral region 4, and the n-type impurities are injected to the front surface 21 of the semiconductor substrate 2 that is exposed from the mask 51. The n-type impurities are injected to the element regions 3 of the semiconductor substrate 2. As the n-type impurities, for example, phosphorus may be exemplified. Due to this, the n-type source regions 11 are formed. The n-type source regions 11 are formed on the front surface side of the base region 12. The mask 51 is removed after having formed the source regions 11.

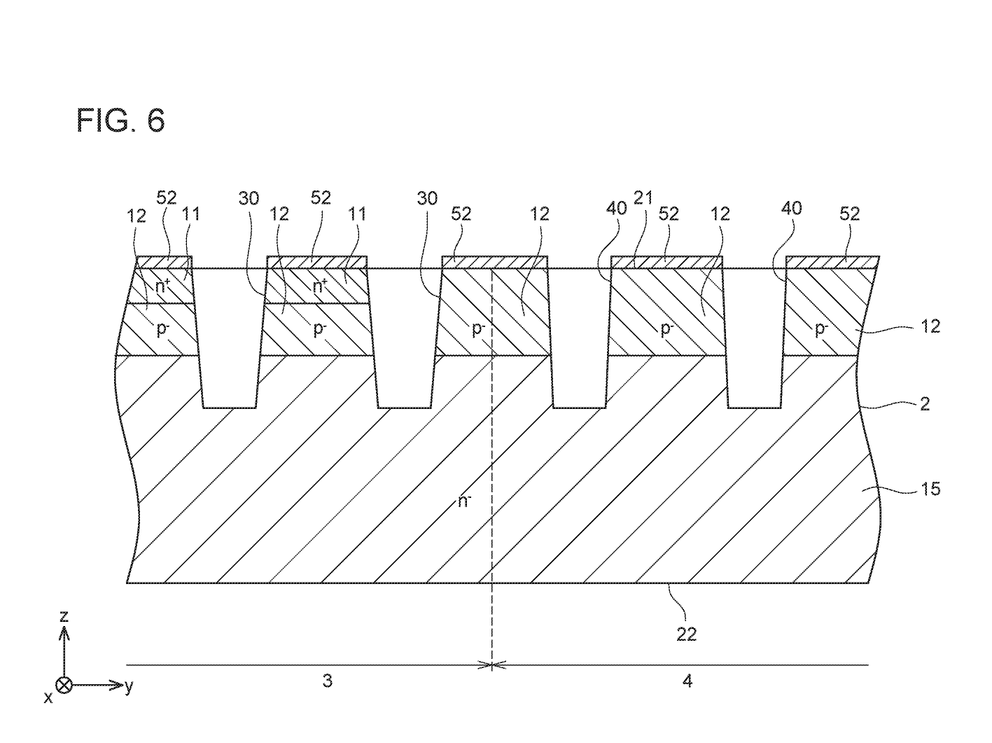

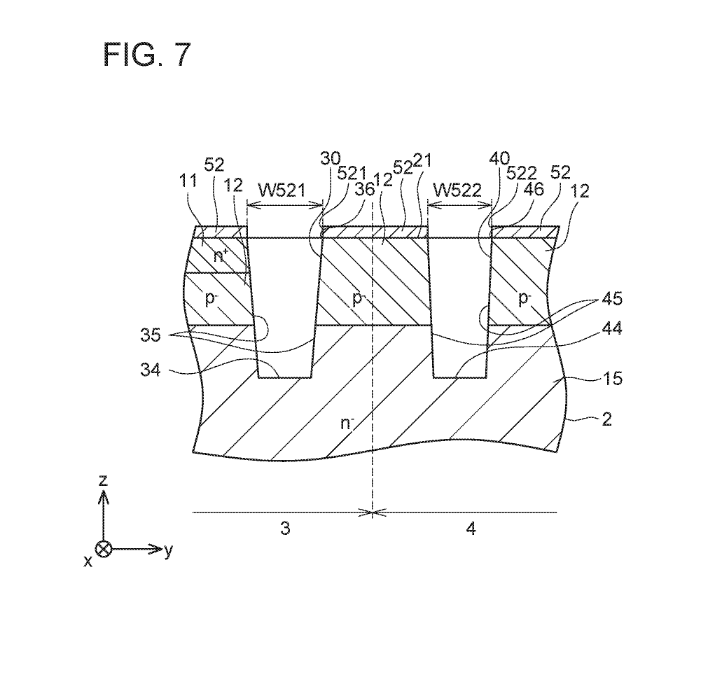

Next, as shown in FIG. 6, a mask 52 is formed on the front surface 21 of the semiconductor substrate 2, and the front surface 21 of the semiconductor substrate 2 exposed from the mask 52 is etched. As shown in FIG. 7, the mask 52 comprises first openings 521 and second openings 522. The first openings 521 open on the element regions 3 of the semiconductor substrate 2, and the second openings 522 open on the peripheral region 4 of the semiconductor substrate 2. The front surface 21 in the element regions 3 of the semiconductor substrate 2 is exposed in the first openings 521, and the front surface 21 in the peripheral region 4 of the semiconductor substrate 2 is exposed in the second openings 522. A width w521 of each of the first openings 521 of the mask 52 is larger than a width w522 of each of the second openings 522 of the mask 52.

The gate trenches 30 are formed by etching the semiconductor substrate 2 exposed in the first openings 521. The terminal trenches 40 are formed by etching the semiconductor substrate 2 exposed in the second openings 522. The front surface 21 of the semiconductor substrate 2 is etched to be dug deep in the depth direction (z direction) of the semiconductor substrate 2. In the element regions 3 of the semiconductor substrate 2, the etching is carried out from the front surface 21 of the semiconductor substrate 2, penetrating the source regions 11 and the base region 12, to positions reaching the drift region 15. In the peripheral region 4 of the semiconductor substrate 2, the etching is carried out from the front surface 21 of the semiconductor substrate 2, penetrating the base region 12, to positions reaching the drift region 15. Due to this, the gate trenches 30 extending toward the rear surface 22 side from the front surface 21 of the semiconductor substrate 2 are formed in the element regions 3. Further, the terminal trenches 40 extending toward the rear surface 22 side from the front surface 21 of the semiconductor substrate 2 are formed in the peripheral region 4. The gate trenches 30 and the terminal trenches 40 are formed so that the inclination of the side surface 35 relative to the bottom surface 34 of each gate trench 30 becomes smaller than the inclination of the side surface 45 relative to the bottom surface 44 of each terminal trench 40. That is, the gate trenches 30 and the terminal trenches 40 are formed so that the angle θ35 between the bottom surface 34 and the side surface 35 of each gate trench 30 becomes larger than the angle θ45 between the bottom surface 44 and the side surface 45 of each terminal trench 40 (trench forming step). When the width w521 of each of the first openings 521 is larger than the width w522 of each of the second openings 522 in the mask 52, the angle θ35 between the bottom surface 34 and the side surface 35 of each gate trench 30 becomes larger than the angle θ45 between the bottom surface 44 and the side surface 45 of each terminal trench 40 when the gate trenches 30 and the terminal trenches 40 are formed by etching in the SiC semiconductor substrate 2. Etching conditions are suitably adjusted upon etching the semiconductor substrate 2.

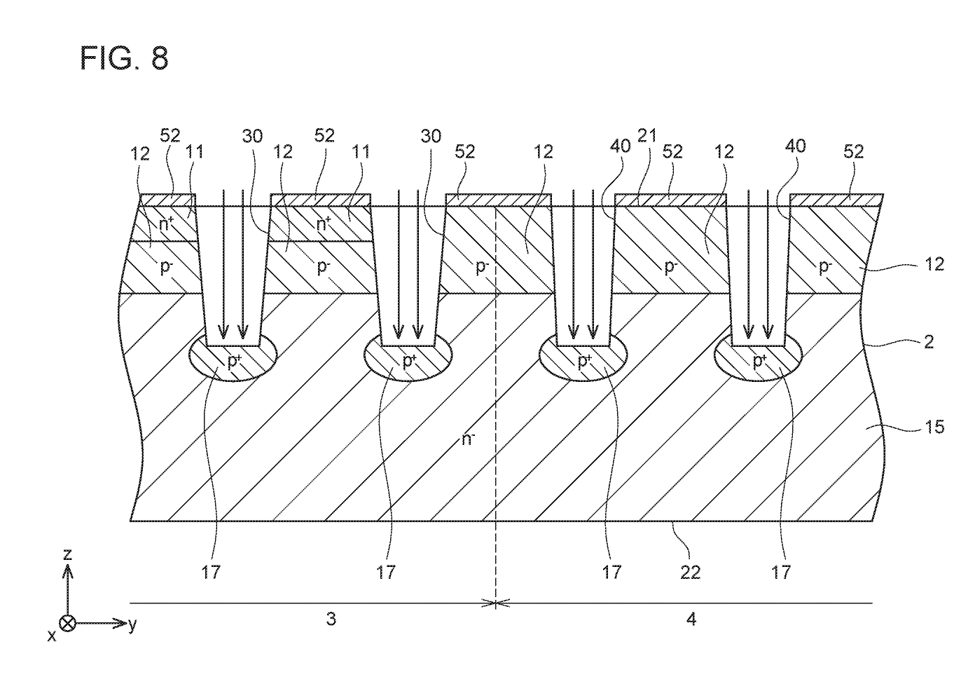

Next, as shown in FIG. 8, the p-type impurities are injected to the bottoms of the gate trenches 30 and the bottoms of the terminal trenches 40. As the p-type impurities, for example, aluminum and boron may be exemplified. Due to this, the floating regions 17 are formed. The floating regions 17 are formed around the bottoms of the gate trenches 30 and around bottoms of the terminal trenches 40. The mask 52 is removed after having formed the floating regions 17.

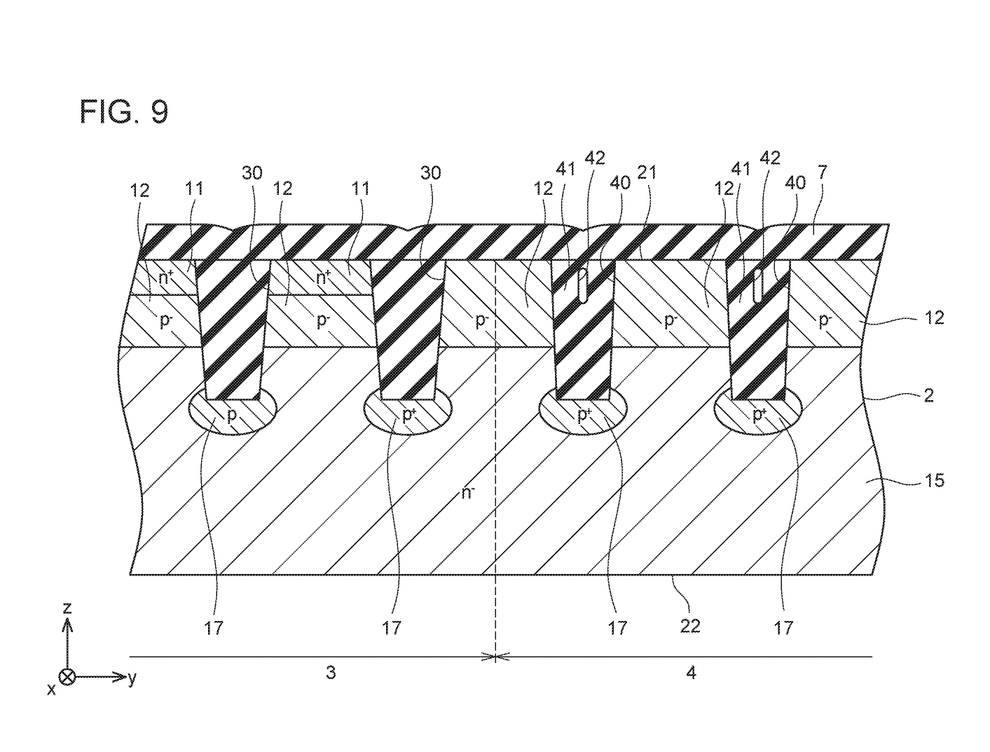

Next, as shown in FIG. 9, an insulator is deposited by a CVD (Chemical Vapor Deposition) method on the semiconductor substrate 2 in which the gate trenches 30 and the terminal trenches 40 have been formed. The insulator is deposited on the front surface 21 of the semiconductor substrate 2, inner surfaces of the gate trenches 30, and inner surfaces of the terminal trenches 40. Due to this, the insulator 41 is deposited inside the gate trenches 30 and the terminal trenches 40 (deposition step). Further, the front surface 21 of the semiconductor substrate 2 is covered by the front surface insulation film 7.

In the deposition step, deposition speed of the insulator 41 when the insulator 41 is deposited inside the gate trenches 30 and the terminal trenches 40 differs depending on locations. More specifically, the deposition speed of the insulator 41 in vicinities of the openings 36 for the gate trenches 30 is faster than the deposition speed of the insulator 41 in vicinities of the bottom surfaces 34 of the gate trenches 30. Further, the deposition speed of the insulator 41 in vicinities of the openings 46 for the terminal trenches 40 is faster than the deposition speed of the insulator 41 in vicinities of the bottom surfaces 44 of the terminal trenches 40.

Further, in the semiconductor substrate 2 of the embodiment, the angle θ35 between the bottom surface 34 and the side surface 35 of each gate trench 30 is larger than the angle θ45 between the bottom surface 44 and the side surface 45 of each terminal trench 40. Thus, the inclination of the side surface 35 relative to the bottom surface 34 of each gate trench 30 is smaller than the inclination of the side surface 45 relative to the bottom surface 44 of each terminal trench 40. Due to this, a difference between the width w36 of the opening 36 and the width w34 of the bottom surface 34 in each gate trench 30 becomes large, whereas in the terminal trenches 40, a difference between the width w46 of the opening 46 and the width w44 of the bottom surface 44 becomes small.

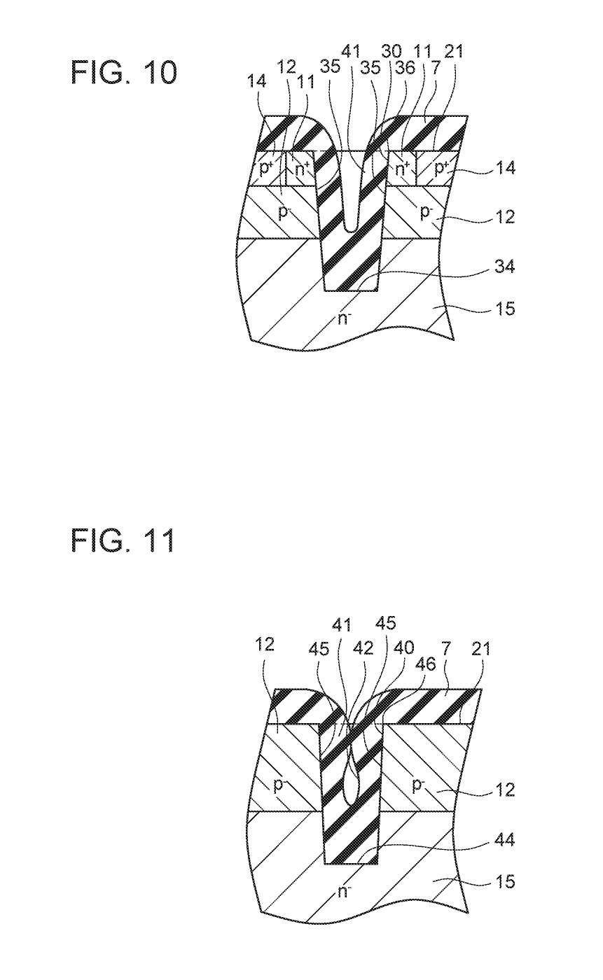

Due to this, when the insulator 41 is deposited in the gate trenches 30 and in the terminal trenches 40, in each of the gate trenches 30, the insulator 41 is deposited orderly from the bottom surface 34 toward the opening 36 before the vicinity of the opening 36 is filled by the insulator 41 as shown in FIG. 10. That is, due to the large difference between the width w36 of the opening 36 and the width w34 of the bottom surface 34 in each gate trench 30, the vicinity of the opening 36 would not be closed by the insulator 41 before a portion deeper than the opening 36 is filled up by the insulator 41, even if the deposition speed of the insulator 41 in the vicinity of the opening 36 of the gate trench 30 is faster than the deposition speed of the insulator 41 in the vicinity of the bottom surface 34 of the gate trench 30.

Contrary to this, in each terminal trench 40, as shown in FIG. 11, the vicinity of the opening 46 is filled by the insulator 41 before the insulator 41 is filled orderly from the bottom surface 44 toward the opening 46. That is, unlike the gate trenches 30, due to the small difference between the width w46 of the opening 46 and the width w44 of the bottom surface 44 in each terminal trench 40, the vicinity of the opening 46 would be closed by the insulator 41 before a portion deeper than the opening 46 is filled up by the insulator 41. As a result, the voids 42 are formed in the insulator 41 deposited in the terminal trenches 40.

Accordingly, due to the difference in the angle θ35 between the bottom surface 34 and the side surface 35 of each gate trench 30 and the angle θ45 between the bottom surface 44 and the side surface 45 of each terminal trench 40, the gate trenches 30 are filled by the insulator 41, whereas the voids 42 are formed in the insulator 41 deposited in the terminal trenches 40.

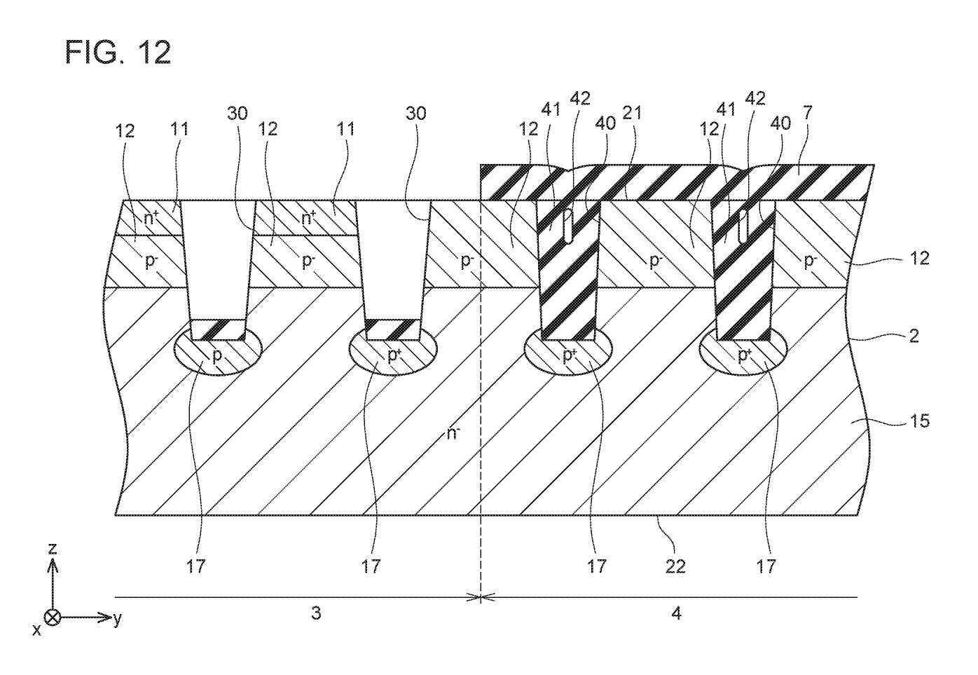

Next, as shown in FIG. 12, the insulator 41 formed on the front surface 21 in the element regions 3 of the semiconductor substrate 2 and the insulator 41 filled in the gate trenches 30 are etched. Unnecessary portions of the insulator 41 are removed by the etching.

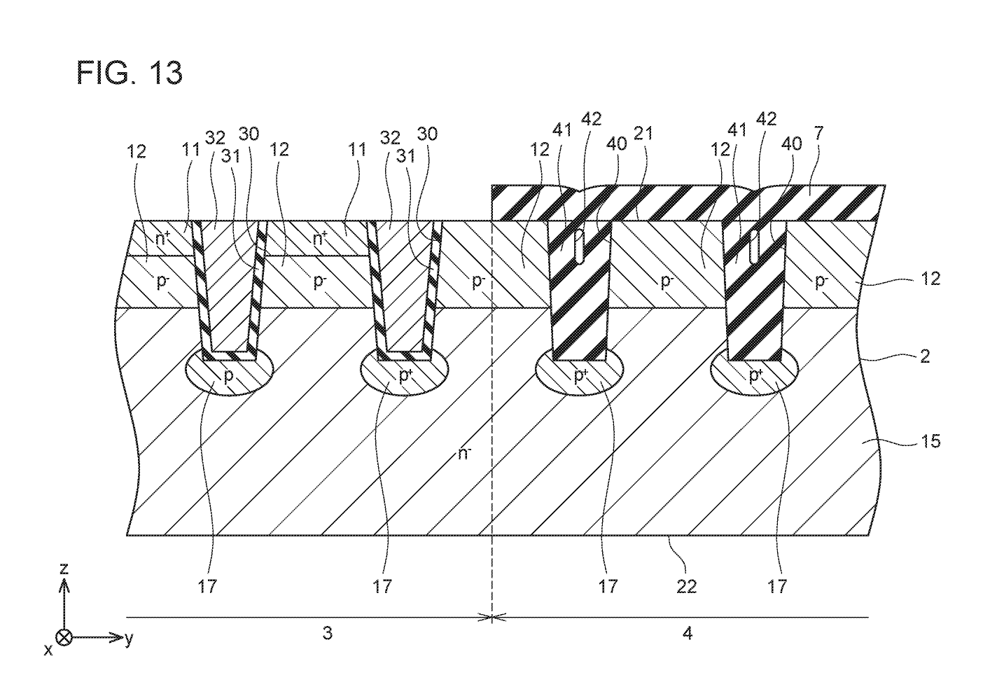

Next, the semiconductor substrate 2 having undergone the deposition step is heated (heat treatment step). As shown in FIG. 13, the inner surfaces of the gate trenches 30 are thermally oxidized by the heating, and the gate insulators 31 are thereby formed. In the heat treatment step, the thermal stress is relaxed by the voids 42 formed in the insulator 41. Thereafter, the gate electrodes 32 are formed in the gate trenches 30 by the CVD method.

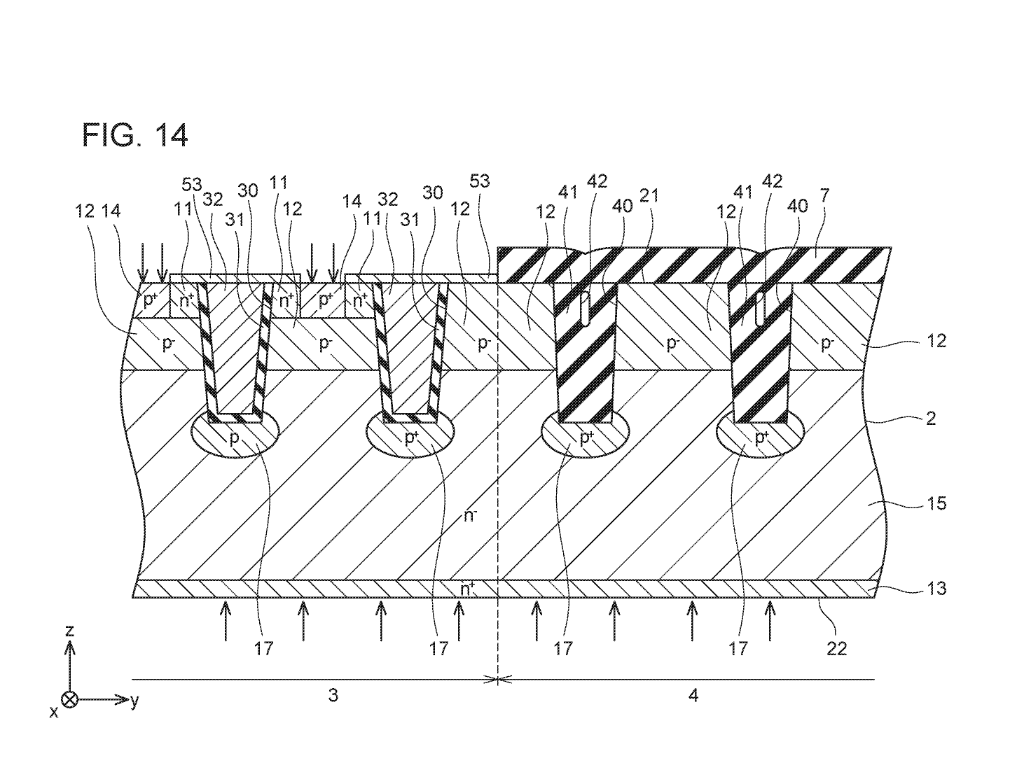

Next, as shown in FIG. 14, a mask 53 is formed on the front surface 21 of the semiconductor substrate 2, and the p-type impurities are injected to the front surface 21 of the semiconductor substrate 2 that is exposed from the mask 53. The p-type impurities are injected to the element regions 3 of the semiconductor substrate 2. As the p-type impurities, for example, aluminum and boron may be exemplified. Due to this, the p-type contact regions 14 are formed. The p-type contact regions 14 are formed on the front surface side of the base region 12. The contact regions 14 are formed next to the source regions 11. The mask 53 is removed after having formed the contact regions 14.

Further, as shown in FIG. 14, the n-type impurities are injected to the rear surface 22 of the semiconductor substrate 2. As the n-type impurities, for example, phosphorus may be exemplified. Due to this, the n-type drain region 13 is formed. The drain region 13 is formed on the rear surface side of the drift region 15.

Subsequently, the interlayer insulation films 33 are formed on the gate electrodes 32. Further, the front surface electrodes 5 are formed on the front surface 21 of the semiconductor substrate 2, and the rear surface electrode 6 is formed on the rear surface 22 of the semiconductor substrate 2. According to the above, the semiconductor device 1 as shown in FIG. 2 is manufactured.

According to the aforementioned method of manufacture, upon performing the heat treatment step after having performed the deposition step, the voids 42 formed within the insulator 41 can relax the thermal stress generated due to the relative expansion or contraction of the insulator 41, even if the insulator 41 filled in the terminal trenches 40 expands or contracts relative to the semiconductor substrate 2 by the temperature change during the heat treatment step. Due to this, the generation of a crack in the insulator 41 and/or the semiconductor substrate 2 can be prevented.

An embodiment has been described above, however, the specific configuration is not limited to the aforementioned embodiment. For example, in the above embodiment, MOSFETs were described as the semiconductor elements formed in the element regions 3, however, no limitation is made to this configuration. In another embodiment, an IGBT (Insulated Gate Bipolar Transistor) may be used as the semiconductor element.

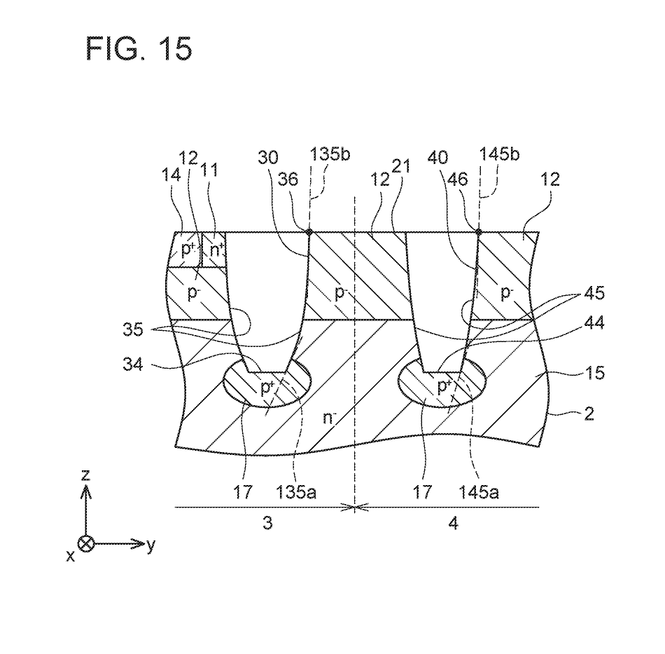

Further, in the above embodiment, the inclination of the side surface 35 relative to the bottom surface 34 of each gate trench 30 is constant from the bottom surface 34 of each gate trench 30 to the front surface 21 of the semiconductor substrate 2, however, no limitation is made to this configuration. Further, the inclination of the side surface 45 relative to the bottom surface 44 of each terminal trench 40 is constant from the bottom surface 44 of each terminal trench 40 to the front surface 21 of the semiconductor substrate 2, however, no limitation is made to this configuration. In another embodiment, as shown in FIG. 15, each of side surfaces 35 of gate trenches 30 and side surfaces 45 of terminal trenches 40 may be curved. In this case, the inclination of the side surface 35 relative to a bottom surface 34 of each gate trench 30 and the inclination of the side surface 45 relative to a bottom surface 44 of each terminal trench 40 would become different depending on depths. Thus, the angle formed by the bottom surface 34 and the side surface 35 of each gate trench 30 and the angle formed by the bottom surface 44 and the side surface 45 of each terminal trench 40 would become different depending on depths. The depth by which the inclination of the side surface 35 relative to the bottom surface 34 of each gate trench 30 and the inclination of the side surface 45 relative to the bottom surface 44 of each terminal trench 40 are compared is not particularly limited. Thus, the depth by which the angle formed by the bottom surface 34 and the side surface 35 of each gate trench 30 and the angle formed by the bottom surface 44 and the side surface 45 of each terminal trench 40 is not particularly limited. For example, an angle formed by a tangent of the bottom surface 34 and the side surface 35 of each gate trench 30 and an angle formed by a tangent of the bottom surface 44 and the side surface 45 of each terminal trench 40 may be compared.

In comparing the inclination of the side surface 35 relative to the bottom surface 34 of each gate trench 30 and the inclination of the side surface 45 relative to the bottom surface 44 of each terminal trench 40, for example, the comparison may be carried out based on a portion where the bottom surface 34 and the side surface 35 of each gate trench 30 make contact and a portion where the bottom surface 44 and the side surface 45 of each terminal trench 40 make contact. That is, the inclination of the side surface 35 relative to the bottom surface 34 of each gate trench 30 corresponds to an inclination of a tangent 135a of the side surface 35 of the gate trench 30 at the portion where the bottom surface 34 and the side surface 35 of the gate trench 30 make contact. Further, the inclination of the side surface 45 relative to the bottom surface 44 of each terminal trench 40 corresponds to an inclination of a tangent 145a of the side surface 45 of the terminal trench 40 at the portion where the bottom surface 44 and the side surface 45 of the terminal trench 40 make contact. The angle between the bottom surface 34 and the side surface 35 of each gate trench 30 corresponds to an angle between the bottom surface 34 of the gate trench 30 and the tangent 135a. Further, the angle between the bottom surface 44 and the side surface 45 of each terminal trench 40 corresponds to an angle between the bottom surface 44 of the terminal trench 40 and the tangent 145a.

Alternatively, in comparing the inclination of the side surface 35 relative to the bottom surface 34 of each gate trench 30 and the inclination of the side surface 45 relative to the bottom surface 44 of each terminal trench 40, for example, the comparison may be carried out based on the openings 36 of the gate trenches 30 and the openings 46 of the terminal trenches 40. That is, the inclination of the side surface 35 relative to the bottom surface 34 of each gate trench 30 corresponds to an inclination of a tangent 135b of the side surface 35 at the opening 36 of the gate trench 30. Further, the inclination of the side surface 45 relative to the bottom surface 44 of each terminal trench 40 corresponds to an inclination of a tangent 145b of the side surface 45 at the opening 46 of the terminal trench 40. The angle between the bottom surface 34 and the side surface 35 of each gate trench 30 corresponds to an angle between the bottom surface 34 of the gate trench 30 and the tangent 135b. Further, the angle between the bottom surface 44 and the side surface 45 of each terminal trench 40 corresponds to an angle between the bottom surface 44 of the terminal trench 40 and the tangent 145b.

Specific examples of the present invention has been described in detail, however, these are mere exemplary indications and thus do not limit the scope of the claims. The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

An example for the technical elements disclosed in the present specification will herein be explained. It should be noted that the respective technical elements are independent of one another, and are useful solely or in combinations.

A width of an opening of the second trench may be smaller than a width of an opening of the first trench.

What is claimed is:

1. A semiconductor device comprising:
a semiconductor substrate; and
a first trench and a second trench that extend from a front surface of the semiconductor substrate toward a rear surface side of the semiconductor substrate,
wherein
a gate electrode is accommodated in the first trench,
an insulator is accommodated in the second trench,
an angle between a bottom surface and a side surface of the first trench is larger than an angle between a bottom surface and a side surface of the second trench, and
a void is provided in the insulator in the second trench.

2. The semiconductor device according to claim 1, wherein
a width of an opening of the second trench is smaller than a width of an opening of the first trench.

3. A method for manufacturing a semiconductor device, the method comprising:
forming a first trench and a second trench that extend from a front surface of a semiconductor substrate toward a rear surface side of the semiconductor substrate;
depositing an insulator into the first trench and the second trench; and
heating the semiconductor substrate after the depositing,
wherein
in the forming of the first and second trenches, the first and second trenches are formed so that an angle between a bottom surface and a side surface of the first trench is larger than an angle between a bottom surface and a side surface of the second trench.
